(19) United States
(12) Patent Application Publication
(10) Pub. No.: US 2009/0255574 A1
(43) Pub. Date: Oct. 15, 2009

(54) SOLAR CELL FABRICATED BY SILICON LIQUID-PHASE DEPOSITION

(75) Inventors: Chentao Yu, Sunnyvale, CA (US); Jianming Fu, Palo Alto, CA (US)

Correspondence Address: PARK, VAUGHAN & FLEMING LLP, 2820 FIFTH STREET, DAVIS, CA, 95618-7759, US

(73) Assignee: SIERRA SOLAR POWER, INC., Sunnyvale, CA (US)

(21) Appl. No.: 12/102,490

(22) Filed: Apr. 14, 2008

(51) Int. Cl. H01L 31/072; H01L 31/04; C25D 5/00; H01L 31/0368

(52) U.S. Cl. 136/252; 205/198; 438/97; 257/E31.043

(57) ABSTRACT

One embodiment of the present invention provides a solar cell. The solar cell includes a substrate; a polycrystalline Si (poly-Si) thin-film layer which includes a p⁺ layer situated above the substrate, wherein the poly-Si thin-film layer is hydrogenated; a contact under-layer situated between the foreign substrate and the poly-Si thin-film layer; a metal layer situated below the contact layer, wherein part of the metal layer reaches the p⁺ layer through the contact under-layer; an n-type doped amorphous-Si (a-Si) thin-film layer situated above the poly-Si thin-film layer forming a heterojunction; an optional intrinsic layer situated between the poly-Si thin-film layer and the n-type doped a-Si thin-film layer; a transparent conductive layer situated above the n-type doped a-Si thin-film layer; and a front-side electrode situated above the transparent conductive layer.

### BACKGROUND

1. Field of the Invention

The present disclosure relates to solar cells. More specifically, the present disclosure relates to solar cells fabricated by silicon liquid-phase deposition (LPD).

2. Related Art

The negative environmental impact caused by fossil fuel and the rising fuel cost have resulted in a dire need for cleaner, cheaper alternative energy sources. Among different forms of alternative energy sources, solar power has been favored for its cleanness and wide availability.

A solar cell converts light into electricity using the photoelectric effect. There are several basic solar cell structures, including homo-junction, hetero-junction, p-i-n/n-i-p, and multi-junction. A homo-junction solar cell includes a p-type doped layer and an n-type doped layer of similar material. Light is absorbed near the p-n junction, and photo-generated carriers diffuse into the p-n junction and are separated by the built-in electric field, thus producing an electrical current across the device and external circuitry. A hetero-junction solar cell includes two layers of materials of different bandgaps. For example, a heterojunction solar cell can be made with a p-type doped single or polycrystalline Si layer, and n-type doped amorphous silicon layer and an optional intrinsic (undoped) semiconductor layer (an i-layer) sandwiched between the p-layer and the n-layer. A multi-junction solar cell includes multiple solar cells of different bandgaps stacked on top of one another. Materials that can be used to construct solar cells includes amorphous silicon (a-Si), polycrystalline (poly-Si), crystalline silicon (crystalline Si), cadmium telluride (CaTe), etc. Among various types of solar cells, Si hetero-junction (SHJ) solar cell have attracted great interest for its reported high energy conversion efficiency, which is defined as the ratio between power converted (from absorbed light to an electrical energy) and power collected when the solar cell is connected to an electrical circuit, and simple processing.

Based on industrial surveys, crystalline-Si-wafer based solar cells dominate nearly 90% of the current solar cell market. However, the cost of producing crystalline-Si-wafer based solar cells is high, and the waste of Si material in the processes of ingot-cutting and wafer-polishing has caused a bottleneck in the supply of crystalline Si wafers. Due to the soaring price and the supply shortage of Si material, there has been great interest in alternative ways to make solar cells. Recently, photovoltaic thin-film technology has been drawing vast interest because it can significantly reduce the amount of material used and thus lower the cost of solar cells. Particularly, poly-Si thin-film based solar cell is one of the most promising technologies for its low cost, non-toxicity, abundance of available material, relatively high efficiency, and long-term stability.

Although the thinner the poly-Si film, the lower the material cost for fabricating the solar cell, the thickness of the poly-Si thin film typically needs to be between 30 μm and 75 μm in order to attain both low cost and high efficiency. Liquid-phase deposition (LPD) of thin poly-Si film on a foreign (non-silicon or lower grade, metallurgic Si) substrate can provide high-quality ultra-thin poly-Si film at a lower cost.

### SUMMARY

One embodiment of the present invention provides a solar cell. The solar cell includes a substrate; a polycrystalline Si (poly-Si) thin-film layer which includes a p⁻ layer situated above the substrate, wherein the poly-Si thin-film layer is hydrogenated; a contact under-layer situated between the substrate and the poly-Si thin-film layer; a metal layer situated below the contact layer, wherein part of the metal layer reaches the p⁺ layer through the contact under-layer; an n-type doped amorphous-Si (a-Si) thin-film layer situated above the poly-Si thin-film layer forming a heterojunction; an optional intrinsic layer situated between the poly-Si thin-film layer and the n-type doped a-Si thin-film layer; a transparent conductive layer situated above the n-type doped a-Si thin-film layer; and a front-side electrode situated above the transparent conductive layer.

In a variation on this embodiment, the substrate includes at least one of the following materials: glass, steel, metallurgical Si, graphite, and ceramic materials.

In a variation on this embodiment, the poly-Si thin-film layer is deposited using a liquid-phase deposition (LPD) process at a substrate temperature between 600° C. and 700° C.

In a variation on this embodiment, the contact under-layer includes SiO₂ and/or boron-doped silica glass (BSG).

In a further variation on this embodiment, the contact under-layer includes a plurality of vias. In addition, part of the metal layer is extruded through the vias to be in contact with the p⁺ layer.

In an even further variation on this embodiment, the solar cell further includes a layer of boron material in the contact under-layer.

In a variation on this embodiment, the metal layer comprises at least one of the following materials: Al, Al/Ag alloy, and Al/Ni/Cu alloy.

In a variation on this embodiment, the solar cell further includes a barrier layer, which includes silicon nitride and/or TiO₂, situated between the substrate and the metal layer.

### BRIEF DESCRIPTION OF THE FIGURES

FIG. 1 illustrates the structure of an exemplary SHJ solar cell.

FIG. 2 presents a diagram illustrating the process for fabricating a solar cell in accordance with one embodiment of the present invention.

FIG. 3 presents a diagram illustrating the process for fabricating a solar cell in accordance with one embodiment of the present invention.

FIG. 4 presents a diagram illustrating the process for fabricating a solar cell in accordance with one embodiment of the present invention.

FIG. 5 presents a diagram illustrating the process for fabricating a solar cell in accordance with one embodiment of the present invention.

### DETAILED DESCRIPTION

The following description is presented to enable any person skilled in the art to make and use the invention, and is provided in the context of a particular application and its requirements. Various modifications to the disclosed embodiments will be readily apparent to those skilled in the art, and the general principles defined herein may be applied to other embodiments and applications present invention is not limited to the embodiments shown, but is to be accorded the widest scope consistent with the claims.

### Overview

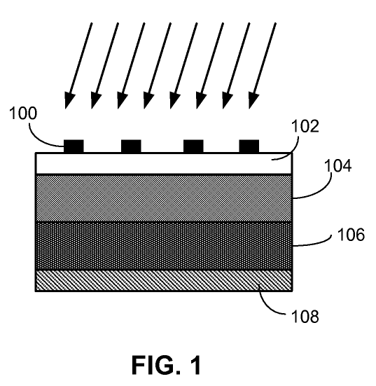

Si hetero-junction (SHJ) solar cells have attracted great attention because of their superior performance. As shown in FIG. 1, an SHJ solar cell can include a metal contact grid 100, a transparent front electrode 102 an n| amorphous silicon (n⁺ a-Si) emitter layer 104, a poly-Si thin-film absorbing layer 106, and an Al back-side electrode 108. Arrows in FIG. 1 indicate incident sunlight. Because surface states often act as recombination centers for charge carriers, surface passivation of the poly-Si layer is a critical process for fabricating high-efficiency solar cells. A hydrogenated a-Si (a-Si:H) layer provides excellent passivation for the poly-Si surface to ensure the high efficiency of the solar cell.

Embodiments of the present invention provide a solar cell fabricated by liquid-phase deposition (LPD) of poly-Si thin film. In one embodiment, a foreign substrate is first covered with a metal layer and a contact under-layer. The contact under-layer ensures the quality of the LPD poly-Si thin film. Then, before molten Si is deposited, the contact under-layer is patterned and etched to form a plurality of vias, which allows the extrusion of the metal layer during the subsequent LPD process. The simultaneous high temperature of the liquid Si, which is around 1428° C. in one embodiment, makes it possible to create a rear electrode ohmic contact, a p⁺ back-surface-field (BSF) layer, and to complete hydrogenation of the poly-Si thin film in one single step.

### Generating P⁺ Layer by Boron Diffusion

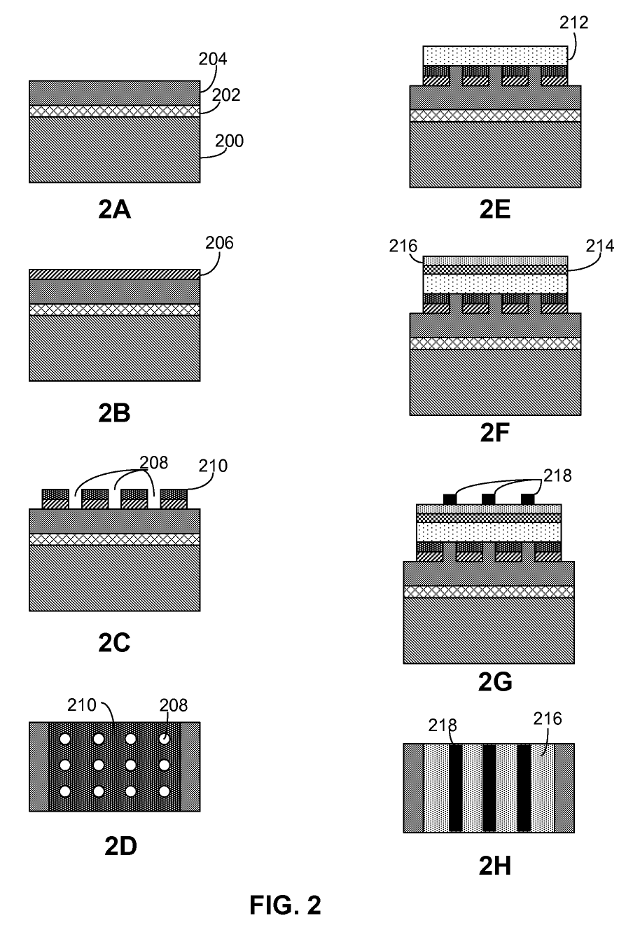

FIG. 2 presents a diagram illustrating the process of fabricating a solar cell based on the LPD of a poly-Si thin film on a foreign substrate in accordance with one embodiment of the present invention.

In operation 2A, a barrier layer 202 and a reflective metal layer 204 are deposited onto a foreign substrate 200. Using a foreign substrate for LPD of poly-Si thin film can lower the fabrication cost. Foreign substrate 200 can include, but is not limited to, at least one of the following materials: glass, steel, graphite, metallurgic Si, and ceramic material. In one embodiment of the present invention, foreign substrate 200 is made of glass. Barrier layer 202 can effectively block the diffusion of metal impurities from the glass substrate into reflective metal layer 204. Barrier layer 202 can include silicon nitride or TiO₂. Reflective metal layer 204 can function as a light reflector and an ohmic contact. Reflective metal layer 204 can include, but is not limited to: Al, Al/Ag alloy, and Al/Ni/Cu alloy. In one embodiment of the present invention, reflective metal layer 204 has a thickness between 1 μm and 50 μm. Geometric patterns, such as zigzags, cross hatches, or connected blocks, can be created on reflective metal layer 204 in order to release stress and to reduce thermal mismatch between metal layer 204 and foreign substrate 200.

In operation 2B, a contact under-layer 206 is deposited on top of reflective metal layer 204. Contact under-layer 206 ensures the quality of the LPD poly-Si thin film. Contact under-layer 206 can include SiO₂ or boron-doped silica glass (BSG).

In operation 2C, contact under-layer 206 is patterned and etched to form a plurality of vias 208. Subsequently, a boron layer 210 is deposited on top of contact under-layer 206. Boron layer 210 provides the boron dopant for subsequently deposited LPD poly-Si layer. Illustration 2D presents the top view of the device after the patterning and etching of contact-under layer 206, and the deposition of boron layer 210. The shapes of vias 208 can be the same or different from each other. It is also possible for vias 208 to have shapes other than circular, such as rectangular, triangular, pentagonal, hexagonal, or other shapes. Boron layer 210 can be formed either by physical-vapor-deposition (PVD) using boron or by plasma-enhanced chemical vapor-deposition (PECVD) using diborane (B₂H₆).

In operation 2E, a layer of poly-Si thin film 212 is deposited. Various thin-film deposition techniques can be used to deposit poly-Si thin film 212. In one embodiment of the present invention, poly-Si thin film 212 is deposited using an LPD technique. The thickness of the LPD poly-Si thin film can be less than 75 μm. Because of the relatively high temperature, often around 1428° C., of the liquid Si, boron from boron material layer 210 can diffuse into poly-Si thin film 212 to form a thin p⁺ receiver layer inside poly-Si thin film 212. The relatively high temperature of the liquid Si can also melt the top surface of metal layer 204. As a result, the molten metal extrudes into vias 208 to directly contact the p⁻ receiver layer, forming an ohmic contact.

In operation 2F, an n-type doped Si thin film 214 and a transparent conductive layer 216 are deposited. N-type doped Si thin film 214 can be formed using a PECVD process, in which a layer of a-Si thin film doped with phosphorous is deposited. Before the deposition of n-type doped Si thin film 214, texturing and a pre-treatment of the underlying poly-Si surface can ensure high efficiency of the solar cell. Such a pre-treatment can be done by turning on NH₃ or H₂ plasma in the PECVD chamber. Transparent conductive layer 216 acts as both an antireflective layer, which assists sunlight absorption, and a conductive layer. In one embodiment of the present invention, transparent conductive layer 216 is highly transparent to a wide spectrum range and has a low electrical resistance. Transparent conductive layer 216 can include aluminum-doped ZnO (AZO) and indium-tin-oxide (ITO). Other materials are also possible for forming transparent conductive layer 216 as long as they are transparent and have low resistance. In one embodiment of the present invention, transparent conductive layer 216 has a thickness of 800 Å±100 Å and a refractive index of about 2.0.

In operation 2G, front-side electrodes 218 are deposited on top of transparent conductive layer 216. Front-side electrodes 218 can be of various materials deposited using various techniques. In one embodiment of the present invention, front-side electrodes 218 are formed by printing Ag or Ti/Pd/Ag lines on transparent conductive layer 216. Illustration 2H shows the top view of the device after front-side electrodes 218 are deposited on transparent conductive layer 216.

### Generating P⁺ Layer by Forming Al-Back Surface Field

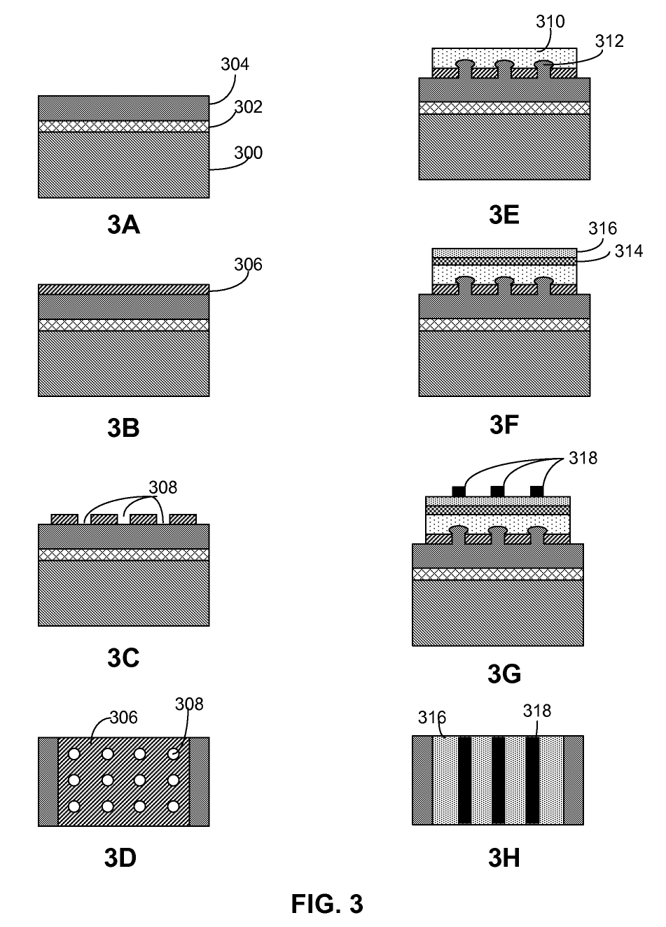

FIG. 3 presents a diagram illustrating the process of fabricating a solar cell based on LPD of poly-Si thin film on a foreign substrate in accordance with one embodiment of the present invention.

Operations 3A and 3B are similar to operations 2A and 2B, respectively. A barrier layer 302, a reflective metal layer 304, and a contact under-layer 306 are deposited onto a foreign substrate 300. Materials used for foreign substrate 300, barrier layer 302, and contact under-layer 306 can be similar to the ones used in operations 2A and 2B. Reflective metal layer 304 includes Al.

In operation 3C, contact under-layer 306 is patterned and etched, and as a result, a plurality of vias 308 is formed in contact under-layer 306. Illustration 3D shows the top view of the device after the patterning and etching of contact-under layer 306. Similar to vias 208, vias 308 can have shapes other than circular, such as rectangular, triangular, pentagonal, hexagonal, or other irregular shapes.

Operation 3E is similar to operation 2E, in which a layer of poly-Si thin film 310 is deposited. A high-temperature LPD technique is used to deposit poly-Si thin film 310. During the LPD process, part of Al metal layer 304 extrudes through vias 308 into poly-Si thin film 310. Inside poly-Si thin film 310, Al can act as a p-type dopant to form Al doped p⁺ Si regions, such as region 312, which are often referred to as Al-back-surface fields (Al-BSF). In the meantime, because Al metal layer 304 is now in direct contact with the p⁺ Si region, an ohmic-contact is formed. Note that the short distance between the p⁺ Si regions and the mobile carriers enables effective collection of mobile carriers at the Al metal layer 304. Therefore, even using low-grade, low-cost silicon material that typically suffers from a short carrier lifetime, the device can still generate high current density.

Operations 3F and 3G are similar to operations 2F and 2G, respectively, in which an n-type doped Si thin film 314, a transparent conductive layer 316, and front-side electrodes 318 are deposited. The deposition processes and the material compositions of n-type doped Si thin film 314, transparent ohmic-contact layer 316, and front-side electrodes 318 can be similar to those used in operations 2F and 2G. Illustration 3H shows the top view of the device after front-side electrodes 318 are deposited on transparent conductive layer 316.

### Generating P⁺ Layer by Laser-Fired-Contact (LFC) Process

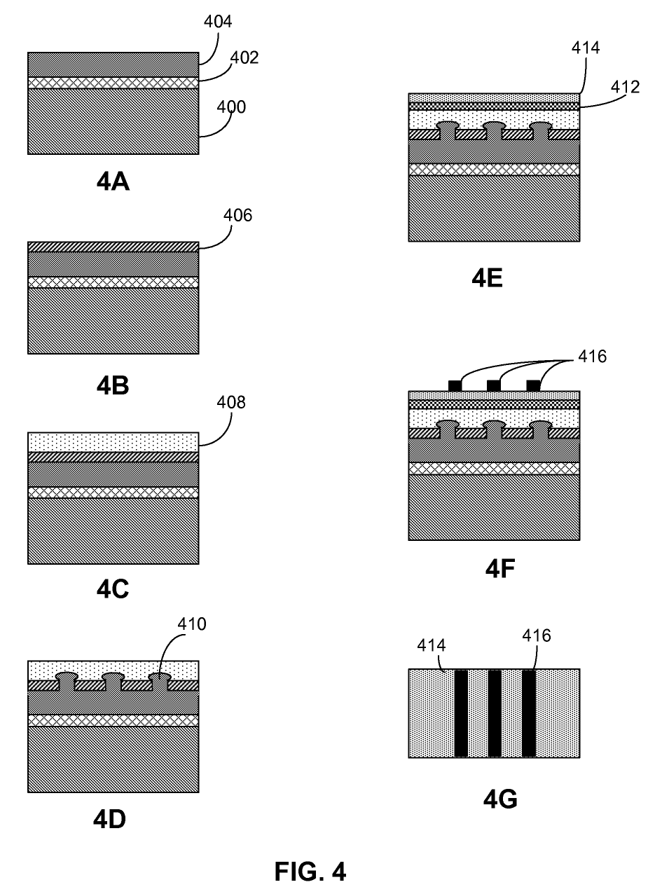

FIG. 4 presents a diagram illustrating the process of fabricating a solar cell based on LPD of poly-Si thin film on a foreign substrate in accordance with one embodiment of the present invention. Operations 4A and 4B are similar to operations 2A and 2B, respectively. A barrier layer 402, a reflective metal layer 404, and a contact under-layer 406 are deposited on a foreign substrate 400. Materials used for foreign substrate 400, barrier layer 402, and contact under-layer 406 can be similar to the ones used in operations 2A and 2B. Reflective metal layer 404 includes Al.

Operation 4C is similar to operation 2E, in which a layer of poly-Si thin film 408 is deposited using an LPD technique.

In operation 4D, a laser-fired-contact (LFC) process is performed in order to form p| Si regions, such as region 410, and to form an ohmic-contact. Specifically, a high power laser is used through glass substrate 400 to fire Al from metal layer 404 locally through the insulating contact under-layer 406. Compared with embodiments illustrated in FIGS. 2 and 3, the LFC process is a cost-effective way to achieve the formation of a p^{|} regions and ohmic contact in one single step.

Operations 4E and 4F are similar to operations 2F and 2G, respectively, in which an n-type doped Si thin film 412, a transparent conductive layer 414, and front-side electrodes 416 are deposited. The deposition processes and material compositions of n-type doped Si thin film 412, transparent conductive layer 414, and front-side electrodes 416 can be similar to those used in operations 2F and 2G. FIG. 4G illustrates the top view of the device after front-side electrodes 416 are deposited on transparent conductive layer 414.

### Generating P⁺ Layer by Al-Wrap-Through

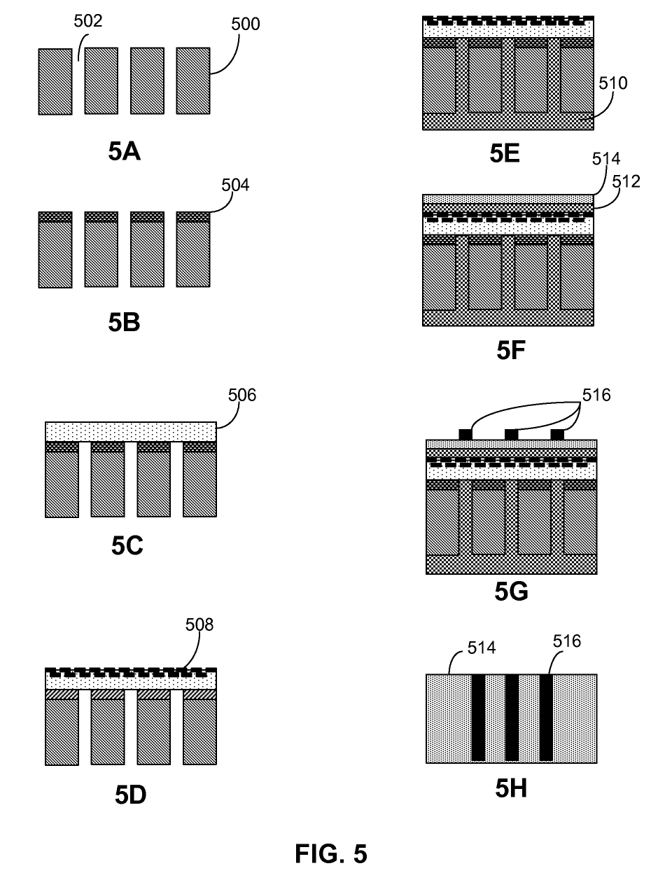

FIG. 5 presents a diagram illustrating the process of fabricating a solar cell based on LPD of poly-Si thin film on a foreign substrate in accordance with one embodiment of the present invention. In operation 5A, a plurality of holes 502 is drilled in a foreign substrate 500. Substrate 500 includes an insulating material, which can be similar to the ones included in substrate 200 used in operation 2A. In operation 5B, a contact under-layer 504 is deposited on foreign substrate 500. Contact under-layer 504 can include boron doped silica glass (BSG) or boron layer.

Operation 5C is similar to operation 2E, in which a layer of poly-Si thin film 506 is deposited using an LPD technique. Note that during the high-temperature LPD process, boron ions inside contact under-layer 504 can diffuse into poly-Si thin film 506 forming a p⁺ poly-Si layer.

In operation 5D, texture 508 is created on the surface of poly-Si thin film 506 in order to reduce sunlight reflection. Texture 508 can be created by a KOH etching or tetramethyl ammonium hydroxide (TMAH) on the surface of poly-Si thin film 506.

In operation 5E, a back-side Al electrode layer 510 is deposited on the back-side of foreign substrate 500. Al can fill holes 502 in foreign substrate 500 to be in contact the p⁺ poly-Si layer. Subsequently, an ohmic-contact can be formed between the Al electrode and the p⁺ poly-Si layer after an annealing process. Back-side Al electrode 510 can be formed using various deposition techniques, including physical-vapor-deposition (PVD), electrochemical-plating (ECP), and aluminum screen printing. In one embodiment of the present invention, back-side Al electrode layer 510 is formed by a PVD of Al/Ni alloy followed by an ECP of Cu. In another embodiment, back-side Al electrode 510 is formed by a PVD of Al/Si alloy, followed by a PVD of TiW, PVD of Cu, ECP of Cu, and an ECP of Sn.

Operations 5F and 5G are similar to operations 2F and 2G, respectively, in which an n-type doped amorphous Si thin film 512 to form a heterojunction between a-Si and poly Si thin film, a transparent conductive layer 514, and front-side electrodes 516 are deposited. The deposition processes and material compositions of n-type doped Si thin film 512, transparent conductive layer 514, and front-side electrodes 516 can be similar to those used in operation 2F and 2G. Illustration 5H shows the top view of the device after front-side electrodes 516 are deposited on transparent conductive layer 514.

### In-Situ Hydrogenation

Hydrogenation of the surface of poly-Si thin film is an important step to improve solar cell efficiency. H atoms can passivate dislocations inside the crystal and defects on grain boundaries by saturating dangling Si bonds. Traditionally, the hydrogenation is performed inside a chamber with high-density H₂ plasma, in which an H₂ molecule dissociates into two H atoms and diffuses into the poly-Si thin film. The high temperature used in the LPD process in embodiments of the present invention makes it possible to perform in-situ hydrogenation by performing the LPD process in an H₂ atmosphere. Under the high temperature, H₂ molecules are separated into H atoms by thermal dissociation. The H₂ atmosphere for the LPD process can be created by mixing H₂ with a number of inert carrier gases, such as He and Ar. The concentration of H₂ can be between 1% and 100%. In one embodiment of the present invention, the mixture of H₂ and Ar carrier gas contains 50% of H₂, and after the high-temperature LPD, the H atom concentration is about 10¹⁹/cm³ in the poly-Si thin film, which is 10 times higher than the case of only 4% H₂ existing in the LPD environment. Note that plasma hydrogenation in other chemical-vapor-deposition (CVD) chamber may still be performed if the in-situ hydrogenation does not provide sufficient passivation at the surface of the poly-Si thin film.

The foregoing descriptions of embodiments of the present invention have been presented only for purposes of illustration and description. They are not intended to be exhaustive or to limit the present invention to the forms disclosed. Accordingly, many modifications and variations will be apparent to practitioners skilled in the art. Additionally, the above disclosure is not intended to limit the present invention. The scope of the present invention is defined by the appended claims.

What is claimed is:

1. A solar cell comprising:
a substrate;
a polycrystalline Si (poly-Si) thin-film layer which includes a p⁺ layer situated above the substrate, wherein the polycrystalline thin-film Si layer is hydrogenated;
a contact under-layer situated between the substrate and the polycrystalline thin-film Si layer;
a metal layer situated below the contact layer, wherein part of the metal layer reaches the p^{|} layer through the contact under-layer;
an n-type doped amorphous Si (a-Si) thin-film layer situated above the polycrystalline thin-film Si layer forming a heterojunction;
an optional intrinsic layer situated between the poly-Si thin-film layer and the n-type doped a-Si thin-film layer;
a transparent conductive layer situated above the n-type doped a-Si thin-film layer; and
a front-side electrode situated above the transparent conductive layer.

2. The solar cell of claim 1, wherein the substrate comprises at least one of the following:
glass;
steel;
graphite;
ceramic material; and
metallurgic Si.

3. The solar cell of claim 1, wherein the poly-Si thin-film layer is deposited using a liquid-phase deposition (LPD) process at a substrate temperature between 600° C. and 700° C.

4. The solar cell of claim 1, wherein the contact under-layer comprises SiO₂ and/or boron-doped silica glass (BSG).

5. The solar cell of claim 4, wherein the contact under-layer comprises a plurality of vias; and
wherein part of the metal layer is extruded through the vias to be in contact with the p⁻ layer.

6. The solar cell of claim 5, further comprising a layer of boron material in the contact under layer.

7. The solar cell of claim 1, wherein the metal layer comprises at least one of the following:
Al;
Al/Ag alloy; and
Al/Ni/Cu alloy.

8. The solar cell of claim 1, further comprising a barrier layer situated between the substrate and the metal layer, wherein the barrier layer comprises silicon nitride and/or TiO₂.

9. A method for fabricating a solar cell, the method comprising:
depositing a metal layer on top of a substrate;
depositing a contact under-layer on top of the metal layer;
depositing a polycrystalline Si (poly-Si) thin-film layer on top of the contact under-layer using an LPD process at a sufficiently high temperature, thereby allowing part of the metal layer to reaches the poly-Si thin-film layer through the contact under layer;
depositing an n-type doped amorphous Si (a-Si) thin-film layer on top of the poly-Si thin-film layer;
depositing a transparent conductive layer on top of the n-type doped a-Si thin-film layer; and
depositing a front-side electrode on top of the transparent conductive layer.

10. The method of claim 9, wherein the substrate comprises at least one of the following:
glass;
steel;
graphite;
metallurgic silicon; and
ceramic material.

11. The method of claim 9, wherein the depositing of the poly-Si thin-film layer comprises using an LPD process at a substrate temperature between 600° C. and 700° C.; and
wherein the LPD process is performed in an H₂ atmosphere which comprises a mixture of H₂ and a number of inert carrier gases, thereby facilitating in-situ hydrogenation of the poly-Si thin-film layer during the LPD process.

12. The method of claim 11, further comprising patterning and etching the contact under-layer to form a plurality of vias in the contact under-layer to allow the metal layer to be extruded through the vias during the LPD process.

13. The method of claim 12, further comprising depositing a layer of boron material on top of the contact under-layer, thereby allowing boron ions inside the boron material to diffuse into the poly-Si thin-film layer to form a p⁺ layer during the LPD process.

14. The method of claim 12, wherein the metal layer comprises Al which acts as a p-type dopant during the LPD process to form a localized p⁺ region to form contact to the poly-Si thin-film layer.

15. The method of claim 9, further comprising using a laser-fired-contact (LFC) process to fire the metal layer through the contact under-layer.

16. The method of claim 15, wherein the metal layer comprises at least one of the following: Al, Al/Ag alloy, and Ai/Ni/Cu alloy; and
wherein Al ions are fired through the contact under-layer to act as a p-type dopant to generate a localized p⁺ region to form contacts to the poly-Si thin-film layer.

17. The method of claim 9, wherein the contact under-layer comprises SiO₂ and/or boron-doped silica glass (BSG).

18. The method of claim 9, wherein the a-Si thin film is deposited using a plasma-enhanced chemical-vapor-deposition (PECVD) process; and
wherein the poly-Si thin-film layer is pretreated with NH₃ or H₂ plasma inside the PECVD chamber.

19. The method of claim 9, further comprising depositing a barrier layer situated on top of the substrate, wherein the barrier layer comprises silicon nitride and/or TiO₂.

20. A method for fabricating a solar cell, the method comprising:
forming a plurality of holes in a substrate;
depositing a contact under-layer on top of the;
depositing a polycrystalline Si (poly-Si) thin-film layer on top of the contact under-layer;
depositing an Al layer on the back-side of the substrate at an elevated temperature, wherein part of the Al fills in the holes and is in contact with the poly-Si thin-film layer to form p+ contacts with the poly-Si thin-film layer after an annealing process;
depositing an n-type doped amorphous Si (a-Si) thin-film layer on top of the poly-Si thin-film layer;
depositing a transparent conductive layer on top of the n-type doped a-Si thin-film layer; and
depositing a front-side electrode on top of the transparent conductive layer.

21. The method of claim 20, wherein the substrate comprises at least one of the following:
glass;
steel;
graphite;
ceramic material; and
metallurgic silicon.

22. The method of claim 20, wherein the poly-Si thin-film layer is formed using an LPD process at a substrate temperature between 600° C. and 700° C.; and
wherein the LPD process is performed in an atmosphere comprising a mixture of H₂ and a number of inert carrier gases, thereby facilitating in-situ hydrogenation of the poly-Si thin film

23. The method of claim 22, wherein the contact under-layer comprises boron-doped silica glass (BSG); and
wherein during the LPD process, boron ions diffuse into the poly-Si thin-film layer forming a p⁺ region.

24. The method of claim 20, wherein depositing the Al electrode comprises using a physical-vapor-deposition (PVD) technique and/or an electrochemical-plating (ECP) technique and/or a screen printing technique.

25. The method of claim 20, wherein the n-type doped a-Si thin-film layer is deposited using a plasma-enhanced chemical-vapor-deposition (PECVD) process; and
wherein the poly-Si thin-film layer is pretreated with NH₃ or H₂ plasma inside the PECVD chamber.
